(19) United States
(12) Patent Application Publication
(10) Pub. No.: US 2007/0004087 A1
(43) Pub. Date: Jan. 4, 2007

(54) CHIP PACKAGING PROCESS

(76) Inventors: Jen-Chieh Kao, Kaohsiung (TW); Kuo-Chung Yee, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,049

(22) Filed: Dec. 15, 2005

(30) Foreign Application Priority Data
Jun. 30, 2005 (TW) 94122096

(51) Int. Cl. H01L 21/00

(52) U.S. Cl. 438/113

(57) ABSTRACT

A chip packaging process is provided. First, a matrix package substrate having a carrying surface with a plurality of scribe lines thereon is provided. The scribe lines divide the package substrate into a plurality of package substrate units. Then, a sealant is formed on each scribe line. A chip is disposed on each package substrate unit. Furthermore, the chip is electrically connected to a corresponding package substrate unit. Thereafter, a transparent cover is disposed over the matrix package substrate. The transparent cover and the matrix package substrate are connected via the sealant. After that, a trimming process along the scribe lines is performed to cut the transparent cover, the matrix package substrate and the sealant.

### CROSS-REFERENCE TO RELATED APPLICATION

This application claims the priority benefit of Taiwan application serial no. 94122096, filed on Jun. 30, 2005. All disclosure of the Taiwan application is incorporated herein by reference.

### BACKGROUND OF THE INVENTION

1. Field of the Invention

The present invention relates to a semiconductor fabrication process. More particularly, the present invention relates to a chip packaging process.

2. Description of the Related Art

With the gradual maturity of semiconductor packaging techniques in the electronics industry, more and more completed photosensitive chips (or wafers) are sent to chip packaging factory for performing additional assembly processes such as wafer cutting, die bonding, curing, wire-bonding, encapsulation, ball implanting or substrate bonding. Finally, the finished products are inspected or functionally tested to ensure the quality of the products. Because of the possibility of integrating the packaged photosensitive chip with other control circuits, analog/digital (A/D) converters and digital signal processing circuits, the cost of production has dropped significantly. As a result, the current demands for these products in the image-processing market have climbed considerably. Furthermore, the reduction in size and volume also meets the demands for the portability of electronic devices.

FIGS. 1A through 1D are diagrams showing the packaging process of a conventional photosensitive chip. First, as shown in FIG. 1A a matrix package substrate 110 is provided. The matrix package substrate 110 has a plurality of scribe lines 112 thereon that divides the matrix package substrate 110 into a plurality of package substrate units 114. Then, as shown in FIG. 1B, a photosensitive chip 120 is disposed on each package substrate unit 114 through wire-bonding or flip-chip bonding. Thereafter, plastic material is dispensed around the periphery of each photosensitive chip 120 to form a plastic frame 130 around the photosensitive chip 120.

Thereafter, as shown in FIG. 1C, a glass substrate 140 is disposed over the matrix package substrate 100. The glass substrate 140 and the matrix package substrate 110 are jointed together through the plastic frame 130. Each plastic frame 140 encloses a sealed area 116 between the glass substrate 140 and a corresponding package substrate unit 114 and the photosensitive chips 120 are disposed inside the respective sealed areas 116. Then, as shown in FIG. 1D, the glass substrate 140 and the matrix package substrate 110 are cut and separated into a plurality of package units 102 by cutting along the scribe lines 112.

However, the conventional chip packaging process requires the deposition of plastics in each one of the package substrate unit 112 to form a sealing plastic frame 130. Hence, the dispensing pathway of the plastic is rather complicated and requires considerable plastic deposition time as well as material. In addition, the plastic frame 130 will limit the available space on the package substrate unit 112 and affect the utilization of the matrix package substrate 100 and the production of the package device 102.

### SUMMARY OF THE INVENTION

Accordingly, at least one objective of the present invention is to provide a chip packaging process capable of simplifying the plastic dispensing route and saving the time for dispensing plastics and some production cost.

At least another objective of the present invention is to provide a chip packaging process capable of improving the utilization of a matrix package substrate and increasing the production of a package device.

To achieve these and other advantages and in accordance with the purpose of the invention, as embodied and broadly described herein, the invention provides a chip packaging process. First, a matrix package substrate having a carrying surface with a plurality of scribe lines thereon is provided. The scribe lines divide the package substrate into a plurality of package substrate units. Then, a sealant is formed on each scribe line. A chip is disposed on each package substrate unit. Furthermore, the chip is electrically connected to a corresponding package substrate unit. Thereafter, a transparent cover is disposed over the matrix package substrate. The transparent cover and the matrix package substrate are connected via the sealant. After that, a trimming process along the scribe lines is performed the cut the transparent cover, the matrix package substrate and the sealant.

In one preferred embodiment of the present invention, after using the sealant to connect the transparent cover and the matrix package substrate, further includes curing the sealant. The method of curing the sealant includes shining ultraviolet light on the sealant or performing a thermal treatment of the sealant, for example.

In one preferred embodiment of the present invention, the process of using the sealant to connect the transparent cover and the matrix package substrate is performed in a low-pressure environment, for example. Furthermore, the chip and its corresponding package substrate unit are electrically connected through wire-bonding or flip-chip bonding, for example.

In one preferred embodiment of the present invention, the aforementioned scribe lines form a network grid pattern, for example.

Accordingly, the chip packaging process in the present invention includes forming a sealant on each scribe line and trimming along the scribe lines to separate the sealant so that the sealant can serve as a plastic frame to seal up the package device. Because the plastic dispensing path in the present invention is simple, considerable processing time and cost is saved. Moreover, the sealant is disposed on the scribe line. Hence, the utilization of the matrix package substrate and the production of the package device are significantly increased. Ultimately, it facilitates the miniaturization of the package device.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are diagrams showing the packaging process of a conventional photosensitive chip.

FIGS. 2A through 2D are diagrams showing the chip packaging process according to one preferred embodiment of the present invention.

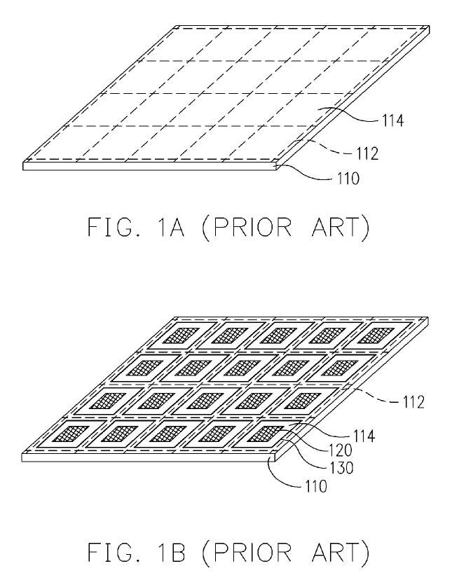

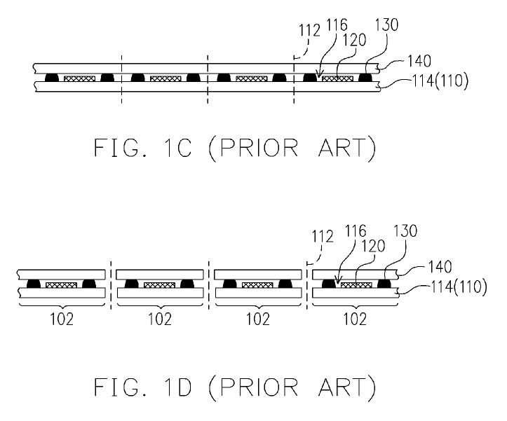

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

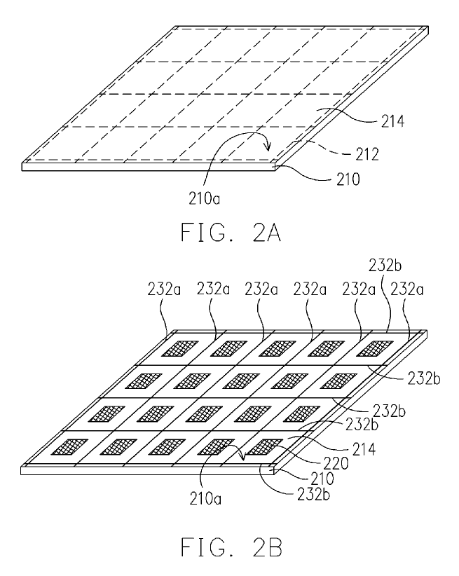

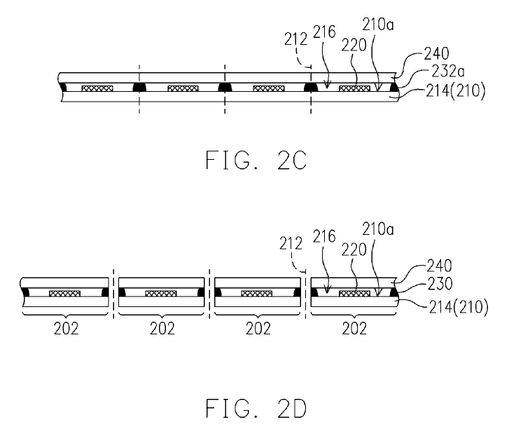

FIGS. 2A through 2D are diagrams showing the chip packaging process according to one preferred embodiment of the present invention. First, as shown in FIG. 2A, a matrix package substrate 210 such as a multi-layered board is provided. The matrix package substrate 210 has a carrying surface 210a and the carrying surface 210a has a plurality of scribe lines 212 thereon for dividing the matrix package substrate 210 into a plurality of package substrate units 214. In one embodiment, the scribe lines 212 together form a network grid pattern so that the package substrate units 214 are aligned to form an array.

As shown in FIG. 2B, plastic material is dispensed on the scribe lines 212 to form strips of sealant 232a and 232b. Then, a chip 220 is disposed on each package substrate unit 214 and the chip 220 is electrically connected to a corresponding package substrate unit 214. The plastics are dispensed in a first direction along the scribe lines 212 to form a plurality of parallel sealant 232a, for example. Thereafter, the plastics are dispensed in a second direction along the scribe lines 212 to form a plurality of parallel sealant 232b such that the sealant 232a and the sealant 232b together form a network grid pattern.

In the present embodiment, the sealant 232a and 232b are fabricated using ultraviolet hardened glue or polymers such as epoxy resin or polyimide. The chip 220 can be a photosensitive chip such as blue-ray photo-diode chip, for example. The chip 220 is electrically connected to the package substrate unit 214 through wire bonding or flip-chip bonding, for example.

In the foregoing step, one may choose to form the sealant 232a and 232b on the matrix package substrate 210 before bonding the chips 220 to the package substrate units 214. In other words, the sealant 232a and 232b are formed on the carrying surface 210a of the matrix package substrate 210 prior to bonding the chips 220 so that the chips 220 can be directly bonded to a matrix package substrate 210 with sealant 232a and 232b already formed thereon. Obviously, the present invention also permits forming the sealant 232a and 232b on the scribe lines 212 after bonding the chips 220 to the package substrate units 214.

As shown in FIG. 2C, a transparent cover 240 is disposed above the matrix package substrate 210. The transparent cover 240 and the matrix package substrate 210 are joined together via the sealant 232a and 232b. The sealant 232a and 232b between the transparent cover 240 and the matrix package substrate 210 enclose a plurality of sealed areas 216 with various chips 220 disposed inside the sealed areas 216. In the present invention, besides connecting the transparent cover 240 with the matrix package substrate 210, the sealant 232a and 232b also serve as a physical medium for maintaining a definite distance of separation between the transparent cover 240 and the matrix package substrate 210. In addition, the transparent cover 240 allows the entrance of light from outside the sealed areas 216. The transparent cover 240 is fabricated using a material such as glass, plastic or other suitable material, for example. After receiving a beam of light, the chip 220 can produce a corresponding light detection signal, for example.

It should be noted that the step of joining the transparent cover 240 and the matrix package substrate 210 together can be carried out in a low-pressure environment to prevent excessive pressure inside the sealed areas 216 from breaking the sealant 232a and 232b. Furthermore, after joining the transparent cover 240 and the matrix package substrate 210 together, a curing process can be performed to cure the sealant 232a and 232b. The method of curing the sealant 232a and 232b includes shining the sealant with ultraviolet light, performing a thermal treatment or some other methods, for example.

Thereafter, as shown in FIG. 2D, a trimming operation is carried out by cutting the transparent cover 240, the matrix package substrate 210 and the sealant 232a and 232b connecting the transparent cover 240 and the matrix package substrate 210 along the scribe lines 232. Hence, a plurality of individual package units 202 is produced. Because the sealant 232a and 232b are formed on the scribe lines 212, cutting along the scribe lines 232 divides the corresponding sealant 232a and 232b up to form plastic frames 230 that encloses each package unit 202.

It should be noted that although the aforementioned embodiment illustrate the chip packaging process for a photosensitive chip, this should by no means limit the present invention as such. For example, the present invention can also be applied to other packaging process involving other chip and matrix package substrate configurations.

In summary, the chip packaging process in the present invention utilizes the sealant formed on the scribe lines to serve as the plastic frame for sealing the package device. Hence, the chip packaging process of the present invention has at least the following advantages.

1. Since the plastic material is dispensed along the scribe lines, the plastic dispensing path is simple. Hence, considerable production time and cost are saved.

2. With the sealant formed on the scribe lines, the usable area on the substrate will not be limited by the sealant so that the utilization of the matrix package substrate and the production of the package device are significantly increased.

3. The full utilization of the area on the substrate facilitates the miniaturization of the package device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip packaging process, comprising the steps of:
providing a matrix package substrate, wherein the matrix package substrate has a carrying surface with a plurality of scribe lines thereon for dividing the matrix package substrate into a plurality of package substrate units;
forming a sealant on each scribe line and disposing a chip on each package substrate unit, wherein the chip is electrically connected to a corresponding package substrate unit;
disposing a transparent cover over the matrix package substrate and joining the transparent cover to the matrix package substrate through the sealant; and
cutting the transparent cover, the matrix package substrate and the sealant along the scribe lines.

2. The chip packaging process of claim 1, wherein after joining the transparent cover and the matrix package substrate through the sealant, further includes curing the sealant.

3. The chip packaging process of claim 2, wherein the step of curing the sealant includes shining a beam of ultraviolet light on the sealant.

4. The chip packaging process of claim 2, wherein the step of curing the sealant includes performing a thermal treatment on the sealant.

5. The chip packaging process of claim 1, wherein the step of joining the transparent cover to the matrix package substrate includes is carried out in a low-pressure environment.

6. The chip packaging process of claim 1, wherein the step of electrically connecting the chip and the corresponding package substrate unit includes performing a wire-bonding process.

7. The chip packaging process of claim 1, wherein the step of electrically connecting the chip and the corresponding package substrate unit includes performing a flip-chip bonding process.

8. The chip packaging process of claim 1, wherein the scribe lines forms a network grid pattern.
